(19) United States
(12) Patent Application Publication
(10) Pub. No.: US 2025/0031471 A1
(43) Pub. Date: Jan. 23, 2025

(54) PHOTOELECTRIC CONVERSION DEVICE AND EQUIPMENT

(71) Applicant: CANON KABUSHIKI KAISHA, Tokyo (JP)

(72) Inventor: TAKESHI AOKI, Kanagawa (JP)

(21) Appl. No.: 18/761,572

(22) Filed: Jul. 2, 2024

(30) Foreign Application Priority Data
Jul. 18, 2023 (JP) 2023-116924

(51) Int. Cl. H01L 27/146

(52) U.S. Cl. CPC H01L 27/14629; H01L 27/14627; H01L 27/14636; H01L 27/1464; H01L 27/14649

(57) ABSTRACT

A photoelectric conversion device is provided. The device includes: a semiconductor layer having a photoelectric conversion element; a wiring structure; and contact plug that connect the semiconductor layer and a wiring pattern arranged in a wiring layer closest to the semiconductor layer among wiring layers included in the wiring structure. A light reflecting layer through which the contact plug penetrate is arranged between the wiring layer and the semiconductor layer, and the light reflecting layer has a periodic structure in which a first layer constituted by one of a dielectric and a semiconductor and a second layer constituted by one of a dielectric and a semiconductor that are different from the first layer are periodically stacked.

### BACKGROUND OF THE INVENTION

### Field of the Invention

The present disclosure relates to a photoelectric conversion device and equipment.

### Description of the Related Art

In Japanese Patent Laid-Open No. 2022-112594, there is disclosed that in a photoelectric conversion element using an avalanche photodiode (APD), a reflective metal layer is arranged to overlap the APD in a wiring structure arranged on a surface opposite to a light-incident surface. According to Japanese Patent Laid-Open No. 2022-112594, the sensibility can be improved by reflecting light that has not been fully absorbed by a semiconductor layer to the semiconductor layer by the reflective metal layer.

In Japanese Patent Laid-Open No. 2022-112594, there is disclosed that, by arranging, on different wiring layers, the reflective metal layer connected to the cathode of the APD and a wiring pattern connected to the anode of the APD, a breakdown voltage between the reflective metal layer and the wiring pattern connected to the anode is ensured. On the other hand, a contact plug that connects the anode of the APD with the wiring pattern passes through the wiring layer having the reflective metal layer arranged therein. For this reason, it is necessary to arrange the reflective metal layer and the contact plug taking into consideration the breakdown voltage between the reflective metal layer and the contact plug or other matter, hence the design may become complicated.

Some embodiments of this disclosure aim at providing a technique that is advantageous in improving the sensitivity with a simpler structure.

### SUMMARY OF THE INVENTION

According to some embodiments, a photoelectric conversion device comprising: a semiconductor layer having a photoelectric conversion element; a wiring structure; and contact plug that connect the semiconductor layer and a wiring pattern arranged in a wiring layer closest to the semiconductor layer among wiring layers included in the wiring structure, wherein a light reflecting layer through which the contact plug penetrate is arranged between the wiring layer and the semiconductor layer, and the light reflecting layer has a periodic structure in which a first layer constituted by one of a dielectric and a semiconductor and a second layer constituted by one of a dielectric and a semiconductor that are different from the first layer are periodically stacked, is provided.

Further features of the present invention will become apparent from the following description of exemplary embodiments (with reference to the attached drawings).

### BRIEF DESCRIPTION OF THE DRAWINGS

FIG. 1 is a view showing an arrangement example of a photoelectric conversion device according to an embodiment;

FIG. 2 is a view showing an arrangement example of the pixel array of the photoelectric conversion device in FIG. 1;

FIG. 3 is a block diagram showing an arrangement example of the photoelectric conversion device in FIG. 1;

FIG. 4 is a circuit diagram showing an arrangement example of the pixel of the photoelectric conversion device in FIG. 1;

FIGS. 5A and 5B are explanatory diagrams each illustrating an operation example of the pixel in FIG. 4;

FIG. 6 is a sectional view showing an arrangement example of the pixel of the photoelectric conversion device in FIG. 1;

FIG. 7 is a plan view showing an arrangement example of the pixel in the section between A-A′ in FIG. 6;

FIG. 8 is a plan view showing an arrangement example of the pixel in the section between B-B′ in FIG. 6;

FIG. 9 is a plan view showing an arrangement example of the pixel in the section between C-C′ in FIG. 6;

FIG. 10 is a diagram showing a reflectance relative to a change in the film thickness in a light reflecting layer of the pixel in FIG. 6;

FIG. 11 is a diagram showing a reflectance relative to a change in the refractive index in the light reflecting layer of the pixel in FIG. 6;

FIG. 12 is a sectional view showing a modification of the pixel in FIG. 6;

FIG. 13 is a plan view showing an arrangement example of the pixel in the section between B-B′ in FIG. 12; and

FIG. 14 is a diagram showing an arrangement example of a camera having incorporated the photoelectric conversion device according to the embodiment.

### DESCRIPTION OF THE EMBODIMENTS

Hereinafter, embodiments will be described in detail with reference to the attached drawings. Note, the following embodiments are not intended to limit the scope of the claimed invention. Multiple features are described in the embodiments, but limitation is not made to an invention that requires all such features, and multiple such features may be combined as appropriate. Furthermore, in the attached drawings, the same reference numerals are given to the same or similar configurations, and redundant description thereof is omitted.

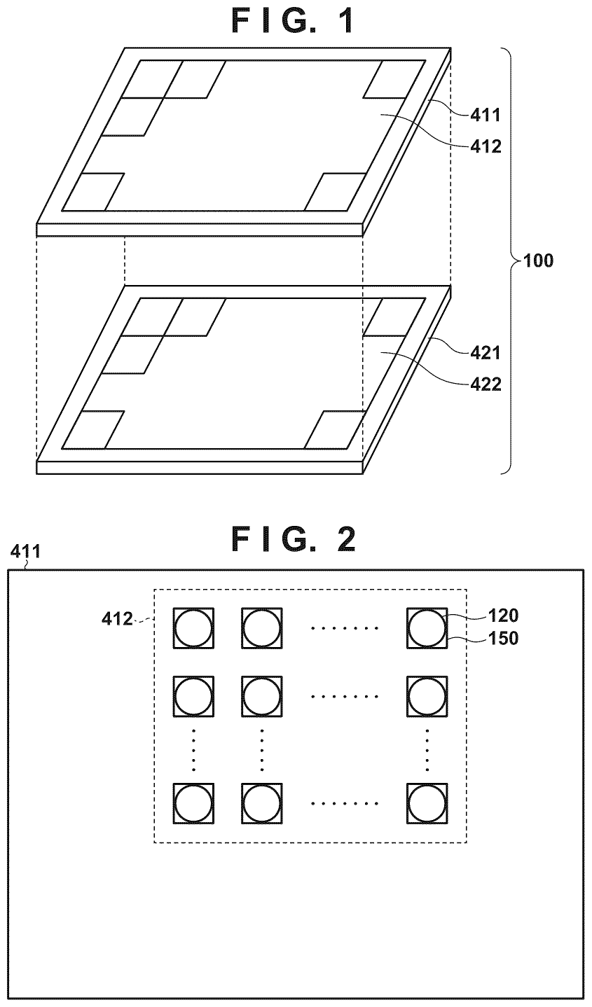

First, an arrangement common to embodiments to be described later will be explained with reference to FIGS. 1 to FIGS. 5A and 5B. FIG. 1 is a view showing an arrangement example of a photoelectric conversion device 100. The photoelectric conversion device 100 may be constituted by stacking two substrates, that is, a sensor substrate 411 and a circuit substrate 421 and electrically connecting them. In other words, the photoelectric conversion device 100 may be a stacked device. On the sensor substrate 411, a semiconductor layer 300 in which a plurality of pixels 150 are arranged, a wiring structure 310, and the like are arranged, which will be described later. On the circuit substrate 421, a semiconductor layer including circuits such as signal processing circuits 253 that process signals output from the pixels 150, a wiring structure, and the like are arranged. The photoelectric conversion device 100 can be constituted by stacking the semiconductor layer of the circuit substrate 421, the wiring structure of the circuit substrate 421, the wiring structure 310 of the sensor substrate 411, and the semiconductor layer 300 of the sensor substrate 411 in this order. The photoelectric conversion device 100 can be a so-called backside illumination photoelectric conversion device in which light enters from a side opposite to a side where the wiring structure 310 of the semiconductor layer 300 of the sensor substrate 411 is arranged.

In the following, the sensor substrate 411 and the circuit substrate 421 are explained as diced chips, however, are not limited to chips. For example, the sensor substrate 411 and the circuit substrate 421 may be constituted of stacked wafers. The sensor substrate 411 and the circuit substrate 421 may be diced after stacked in a wafer state, or may be made into chips (into individual pieces) from the wafer state, and thereafter, each chip may be stacked and joined.

On the sensor substrate 411, a pixel region 412 provided with a plurality of pixels 150 is arranged. On the circuit board 421, a circuit region 422 that processes signals detected in the pixel region 412 is arranged.

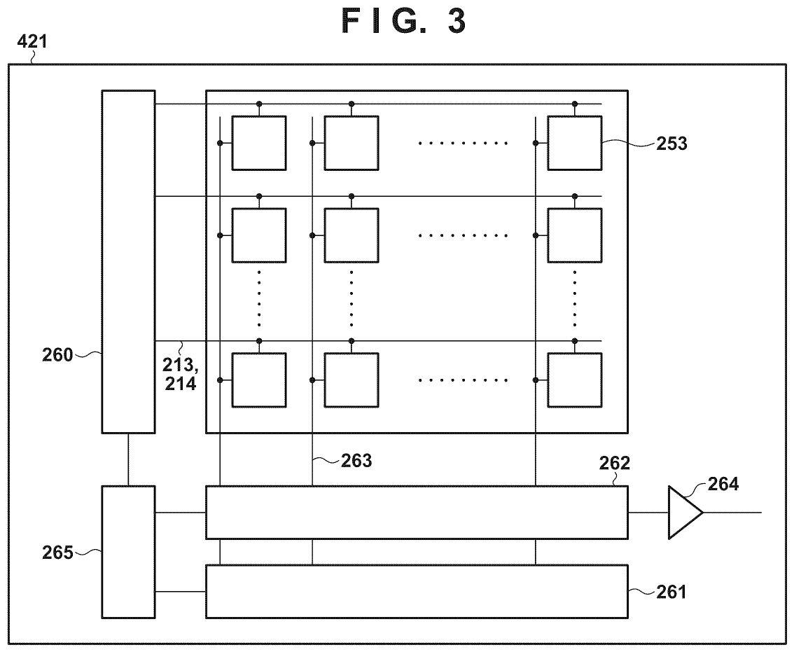

FIG. 2 is a view showing an arrangement example of the sensor substrate 411. The pixels 150 each having a photoelectric conversion element 120 such as an avalanche photodiode (APD) are arrayed two-dimensionally when viewed from the top, forming the pixel region 412. The pixel 150 is typically a pixel for generating an image. However, in a case where the photoelectric conversion device 100 is used in a Time of Flight (ToF) type sensor and the like, the pixel 150 may not necessarily be used for generation of the image. That is, the pixel 150 may be configured to measure the time when light arrives and the quantity of light.

FIG. 3 is a view showing an arrangement example of the circuit substrate 421. The circuit substrate 421 includes signal processing circuits 253 that process charges photoelectrically converted by the photoelectric conversion element 120 shown in FIG. 2, a readout circuit 262, a control pulse generation circuit 265, a horizontal scanning circuit 261, signal lines 263, a vertical scanning circuit 260, and the like. The signal processing circuit 253 shown in FIG. 3 may be arranged in correspondence with the respective pixels 150 shown in FIG. 2. In this case, the pixels 150 (photoelectric conversion elements 120) and the signal processing circuits 253 may be electrically connected via connection wirings provided for the respective pixels 150.

The vertical scanning circuit 260 receives a control pulse supplied from the control pulse generation circuit 265, and supplies the control pulse to the respective pixels 150. A logic circuit such as a shift register or an address decoder can be used for the vertical scanning circuit 260.

A signal output from the pixel 150 is processed by the signal processing circuit 253. A counter, a memory, and the like can be provided in the signal processing circuit 253. The memory can hold, as a digital value, a count value obtained by counting by the counter.

The horizontal scanning circuit 261 inputs, to the signal processing circuit 253, a control pulse for sequentially selecting respective columns in order to read out signals from the memories, in which digital signals are held, of the signal processing circuits 253 corresponding to the respective pixels 150. As for a selected column, a signal is output to the signal line 263 from the signal processing circuit 253 corresponding to the pixel 150 selected by the vertical scanning circuit 260. The signal output to the signal line 263 is output via an output circuit 264 to a recording unit or a signal processing unit outside the photoelectric conversion device 100.

The array of the pixels 150 in the pixel region 412 shown in FIG. 2 is not limited to a two-dimensional array. The pixels 150 may be arranged one-dimensionally. The function of the signal processing circuit 253 need not always be provided one by one in all the pixels 150 (photoelectric conversion elements 120). For example, one signal processing circuit 253 may be shared among the plurality of pixels 150 (photoelectric conversion elements 120) to sequentially perform signal processing.

As shown in FIGS. 2 and 3, a plurality of signal processing circuits 253 can be arranged in a region overlapping the pixel region 412 in an orthogonal projection to the pixel region 412. The vertical scanning circuit 260, the horizontal scanning circuit 261, the readout circuit 262, the output circuit 264, the control pulse generation circuit 265, and the like can be so arranged as to overlap a gap between the end of the sensor substrate 411 and the end of the pixel region 412. In other words, the sensor substrate 411 has the pixel region 412 and a non-pixel region arranged around the pixel region 412. In this case, the vertical scanning circuit 260, the horizontal scanning circuit 261, the readout circuit 262, the output circuit 264, and the control pulse generation circuit 265 can be arranged in a region overlapping the non-pixel region.

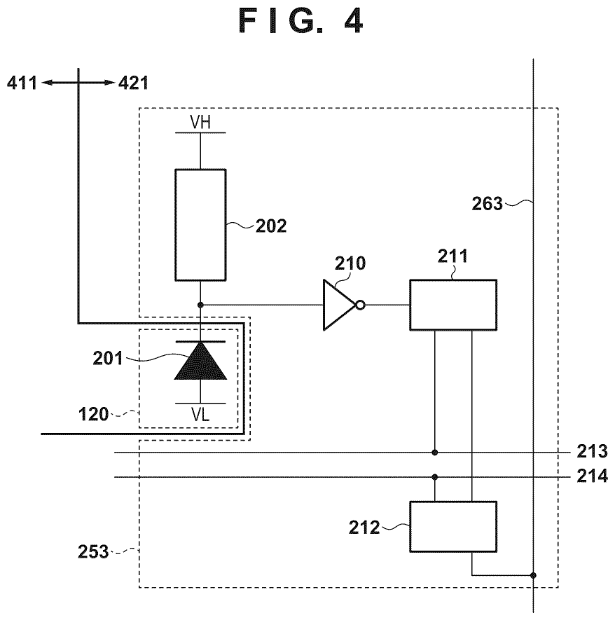

FIG. 4 is an example of a block diagram including an equivalent circuit when paying attention to one pixel 150 (photoelectric conversion element 120). In FIG. 4, the photoelectric conversion element 120 including an APD 201 is provided on the sensor substrate 411, and the remaining components are provided on the circuit board 421.

The APD 201 generates, by photoelectric conversion, a charge pair corresponding to incident light. A potential VL is supplied to the anode of the APD 201. A potential VH higher than the potential VL supplied to the anode is supplied to the cathode of the APD 201. A reverse bias voltage is supplied to the anode and the cathode so that the APD 201 performs an avalanche multiplication operation. In a state in which such a reverse bias voltage is supplied, charges generated by the incident light cause avalanche multiplication, generating an avalanche current.

In a case where the reverse bias voltage is supplied to the APD 201, there are a Geiger mode in which the APD 201 is operated by a potential difference (voltage) between the anode and the cathode larger than a breakdown voltage, and a linear mode in which the APD 201 is operated by a potential difference between the anode and the cathode that is near the breakdown voltage or equal to or lower than it. An APD operated in the Geiger mode is called a Single Photon Avalanche Diode (SPAD). For example, the potential VL is −30 V, and the potential VH is 1 V. The APD 201 may be operated in the linear mode or the Geiger mode.

A quench element 202 is connected between a power supply that supplies the potential VH, and the APD 201. The quench element 202 functions as a load circuit (quench circuit) at the time of signal multiplication by avalanche multiplication, and operates to suppress a voltage supplied to the APD 201 and suppress avalanche multiplication (quench operation). The quench element 202 also operates to return the voltage supplied to the APD 201 back to a voltage (VH-VL) by supplying a current by an amount corresponding to a voltage drop caused by the quench operation (recharge operation).

The signal processing circuit 253 can include a waveform shaping circuit 210, a counter circuit 211, and a selection circuit 212. In this specification, the signal processing circuit 253 suffices to include any of the waveform shaping circuit 210, the counter circuit 211, and the selection circuit 212.

The waveform shaping circuit 210 shapes a potential change of the cathode of the APD 201 that is obtained at the time of photon detection, and outputs a pulse signal. As the waveform shaping circuit 210, for example, an inverter circuit is used. In the arrangement shown in FIG. 4, the use of one inverter as the waveform shaping circuit 210 is exemplified. However, it is not limited to this, and a circuit constituted by series-connecting a plurality of inverters may be used as the waveform shaping circuit 210 or another circuit having the waveform shaping effect may be used.

The counter circuit 211 counts pulse signals output from the waveform shaping circuit 210 and holds the count value. When a control pulse pRES is supplied from the vertical scanning circuit 260 via a driving line 213, the signal held by the counter circuit 211 is reset.

A control pulse pSEL is supplied to the selection circuit 212 from the vertical scanning circuit 260 shown in FIG. 3 via a driving line 214 shown in FIG. 4 to switch the electrical connection or disconnection between the counter circuit 211 and the signal line 263. The selection circuit 212 includes, for example, a buffer circuit or the like for outputting a signal.

A switching element such as a transistor may be interposed between the quench element 202 and the APD 201 or between the photoelectric conversion element 120 and the signal processing circuit 253 so that electrical connection can be switched. Similarly, supply of the potential VH or potential VL to the photoelectric conversion element 120 may be electrically switchable using a switching element such as a transistor.

In this embodiment, the configuration, in which the counter circuit 211 is arranged in the signal processing circuit 253, has been shown. However, it is not limited to this, and a Time-to-Digital Converter (TDC) and a memory may be used instead of the counter circuit 211 so that the photoelectric conversion device 100 obtains a pulse detection timing. In this case, the generation timing of a pulse signal output from the waveform shaping circuit 210 is converted into a digital signal by the TDC. To the TDC, a control pulse pREF (reference signal) is supplied from the vertical scanning circuit 260 via a driving line for measurement of the timing of the pulse signal. By using the control pulse pREF as a reference, the TDC obtains, as a digital signal, a signal when the input timing of a signal output from each pixel 150 via the waveform shaping circuit 210 is regarded as a relative time.

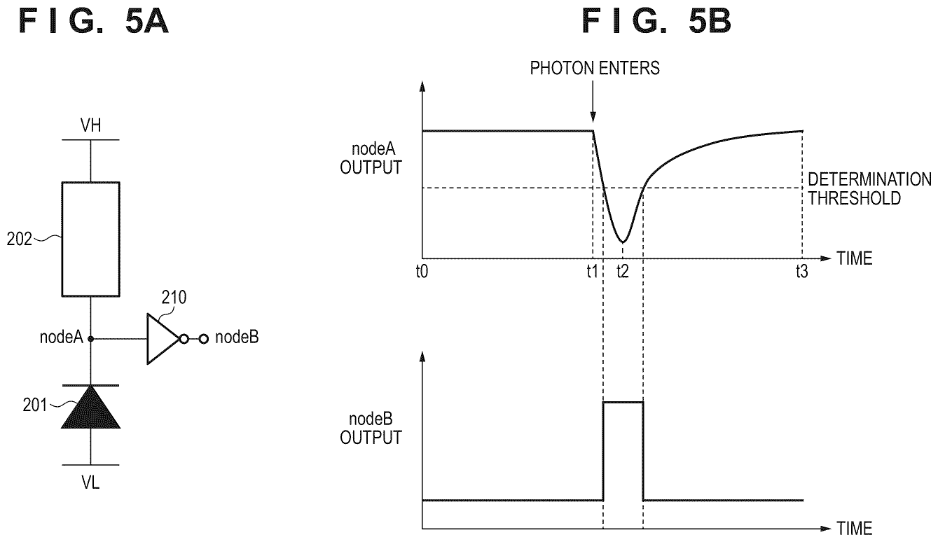

FIGS. 5A and 5B are diagrams schematically showing a relationship between the operation of the APD 201 and an output signal. FIG. 5A is a diagram showing an excerpt of the APD 201, the quench element 202, and the waveform shaping circuit 210 shown in FIG. 4. Here, the input side of the waveform shaping circuit 210 is regarded as a node A and its output side is regarded as a node B. FIG. 5B shows waveform changes at the node A and the node B.

From time t0 to time t1, a potential difference (voltage) of the potential VH−the potential VL is applied to the APD 201. When a photon enters the APD 201 at time t1, the avalanche multiplication occurs in the APD 201, an avalanche multiplication current flows into the quench element 202, and the potential of the node A drops. When the voltage drop amount further increases and the potential difference applied to the APD 201 decreases, as shown at time t2, the avalanche multiplication of the APD 201 stops and the potential level of the node A does not drop any more from a predetermined value. Thereafter, from time t2 to time t3, a current compensating for the voltage drop flows to the node A from a power supply line for supplying the potential VL, and at time t3, the node A is statically determined at the original potential level. At this time, a portion at which the output waveform exceeds a given threshold at the node A is waveform-shaped by the waveform shaping circuit 210 and output as a signal to the node B.

The arrangement of the signal line 263, the readout circuit 262, and the output circuit 264 is not limited to the arrangement shown in FIG. 3. For example, the signal row 263 may be extended and arranged in the row direction (horizontal direction in FIG. 3), and the readout circuit 262 may be arranged at a position where the signal line 263 extends.

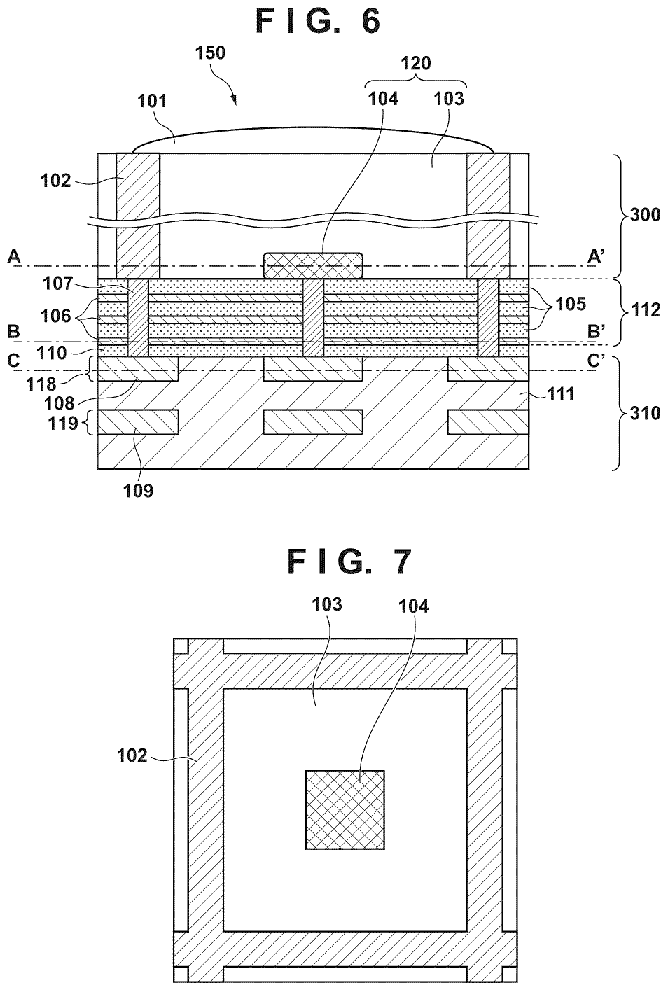

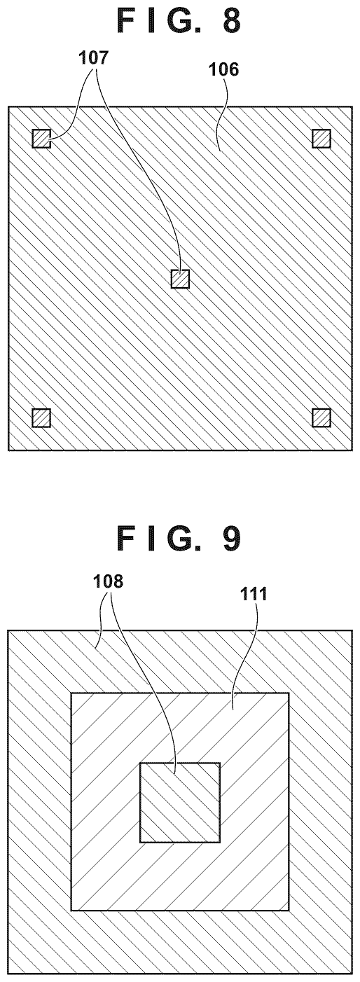

Next, the arrangement of the pixel 150 arranged in the sensor substrate 411 will be explained in detail. FIG. 6 is a cross-sectional view showing an example of the arrangement of one of the plurality of pixels 150 arranged in the pixel region 412 of the photoelectric conversion device 100. In FIG. 6, a cross-section of the sensor substrate 411 is shown, and a description of the circuit substrate 421 to be arranged below the wiring structure 310 is omitted. FIG. 7 is a plan view between A-A′ in FIG. 6. FIG. 8 is a plan view between B-B′ in FIG. 6. FIG. 9 is a plan view between C-C′ in FIG. 6. In the embodiment, the photoelectric conversion element 120 arranged in the pixel 150 will be explained as the avalanche photodiode (APD), but it is not limited to this and may be a photodiode formed using an ordinary PN junction or PIN junction.

As shown in FIG. 6, the pixel 150 arranged in the photoelectric conversion device 100 includes the semiconductor layer 300 having the photoelectric conversion element 120, the wiring structure 310, and contact plugs 107 which connect the semiconductor layer 300 with a wiring pattern 108 arranged in a wiring layer 118 closest to the semiconductor layer 300 between wiring layers 118 and 119 included in the wiring structure 310. Furthermore, in the pixel 150, a light reflecting layer 112 through which the contact plugs 107 penetrate, is arranged between the wiring layers 118 and the semiconductor layer 300. The light reflecting layer 112 has a periodic structure in which a layer 105 formed of a dielectric or a semiconductor and a layer 106 formed of a dielectric or a semiconductor different from the layer 105 are periodically stacked. In other words, combinations of two or more sets of the layers 105 and 106 can be arranged in the light reflecting layer 112. Accordingly, the light reflecting layer 112 can have a configuration of four or more-layer structure. In the arrangement shown in FIG. 6, the light reflecting layer 112 is a six-layer structure with a combination of three sets of the layers 105 and 106. However, it is not limited thereto, and the light reflecting layer 112 may have eight or more layers.

A microlens 101 may be arranged in the pixel 150. The wiring structure 310 has a configuration in which the wiring patterns 108 and 109 are arranged in an interlayer insulating film 111. In the arrangement shown in FIG. 6, an arrangement including two layers of the wiring layers 118 and 119, in which the wiring patterns 108 and 109 are arranged, is shown, but it is not limited thereto, and the wiring layer may be one layer or three or more layers. Between the light reflecting layer 112 and the wiring layer 118, which is closest to the semiconductor layer 300 between the wiring layers 118 and 119 included in the wiring structure 310, an insulating layer 110 is arranged through which the contact plugs 107 penetrate. Each of the pixels 150 is separated by a pixel separation section 102.

The semiconductor region 103 and the semiconductor region 104 constitute the photoelectric conversion element 120. Between the semiconductor region 103 and the wiring layer 118 in which the wiring pattern 108 is arranged, the light reflecting layer 112 in which layers 105 and 106 are stacked periodically is arranged. As described above, the semiconductor layer 300 (semiconductor regions 103 and 104) and the wiring pattern 108 arranged in the wiring layer 118 closest to the semiconductor layer 300 are electrically connected by the contact plugs 107. The contact plug 107 is formed to penetrate the light reflecting layer 112 and the insulating layer 110. Therefore, a thickness of the light reflecting layer 112 is equal to or less than a height of the contact plug 107.

With the above-described configuration, light entered from the microlens 101 passes through the semiconductor region 103, and an optical charge due to a single photon causes the avalanche multiplication in the semiconductor region 104 formed in the semiconductor region 103. Further, light that has not been absorbed by the semiconductor layer 300 is reflected by the light reflecting layer 112 before reaching the wiring pattern 108, and enters the semiconductor layer 300 again. Therefore, the sensitivity of the photoelectric conversion device 100 is improved. Also, the light that has not been absorbed by the semiconductor layer 300 is reflected by the light reflecting layer 112, which is closer to the semiconductor layer 300 than the wiring patterns 108 and 109. Thus, stray light, which occurs when the light entered the pixel 150 reflects on the wiring pattern 108 and the wiring pattern 109 arranged at positions deeper than the light reflecting layer 112 and enters adjacent pixels 150, is suppressed.

In a case where the photoelectric conversion device 120 is an SPAD element using the APD as in the embodiment, a side opposite to the light incident surface (the side on which the microlens 101 is arranged) of the semiconductor layer 300 can be a flat surface on which elements such as a transistor and the like are not arranged. Therefore, the light reflecting layer 112 can be formed on the flat semiconductor layer 300, hence the light reflecting efficiency can be improved.

Next, the configuration of the light reflecting layer 112 will be explained. The layer 105 and the layer 106 are layers whose refractive indices are different from each other. Here, the layer 106 is explained as a layer having a refractive index higher than that of the layer 105. A difference in the refractive index between the layer 105 and the layer 106 may be, for example, 0.6 or more, or 0.8 or more. Furthermore, the difference in the refractive index between the layer 105 and the layer 106 may be 1.0 or more. Here, the refractive index indicates the refractive index for light at a wavelength of 633 nm.

For example, the layer 105 may be a layer composed mainly of silicon oxide. The refractive index of silicon oxide is about 1.45 to 1.46. For the layer 105, a fluoride having a low refractive index, such as magnesium fluoride may be used. On the other hand, the layer 106 can be a layer having a refractive index of 2.3 or more, for example. The layer 106 can contain, for example, at least one of cerium oxide, niobium oxide, titanium oxide, zinc sulfide, amorphous silicon and amorphous germanium. For example, the layer 106 may be amorphous silicon. The refractive index of amorphous silicon is, for example, about 3.4 to 3.6. In this case, amorphous silicon may contain 10 atom % or higher hydrogen. Furthermore, for example, the layer 106 may be amorphous germanium. The refractive index of amorphous germanium is, for example, about 4. In this case, the amorphous germanium may contain 10 atom % or higher hydrogen.

In silicon oxide, amorphous silicon, and amorphous germanium used in the layers 105 and 106 of the light reflecting layer 112, hydrogen can be contained, depending on deposition conditions. Hydrogen binds to dangling bonds existing on the surface of the semiconductor layer 300 using silicon, and reduces a surface level density. Due to reduction of the surface level density, the Dark Count Rate (DCR), which is an index of noise, is lowered, so that noise characteristics of the photoelectric conversion device 100 can be improved. As the structure shown in Japanese Patent Laid-Open No. 2022-112594, when the reflective metal layer is arranged close to the semiconductor layer, part of the interlayer insulating film to which the reflective metal layer is arranged is replaced with a reflective metal layer which does not contain hydrogen. Furthermore, it becomes difficult to supply hydrogen from the interlayer insulating film that is apart from the semiconductor layer more than the reflective metal layer. On the other hand, in the structure shown in FIG. 6, hydrogen can be efficiently supplied from the light reflecting layer 112 to the semiconductor layer 300. Silicon oxide, amorphous silicon, and amorphous germanium that contain hydrogen may be deposited using, for example, a CVD method or a sputtering method.

The insulating layer 110, similar to the layer 105, may be a layer mainly composed of silicon oxide. Further, the interlayer insulating layer 111 constituting the wiring structure 310 may contain at least one of silicon oxide and a material having a dielectric constant lower than silicon oxide. Accordingly, the refractive index of the layer 106 can be higher than that of the insulating layer 110. Also, the refractive index of the layer 106 can be higher than that of the interlayer insulating film 111.

The light reflecting layer 112 constituted by the layer 105 and the layer 106 will be further explained. Assuming now that a central wavelength of light reflected by the light reflecting layer 112 is λ [nm]. At the light reflecting layer 112, the central wavelength of the reflected light can be a wavelength whose reflectance is the highest. In a case where a region whose reflectance is 100% exists, the central wavelength of the reflected light is a wavelength at the center of the region whose reflectance is 100%. In this case, the layers 105 and 106 may be adjusted so that an optical film thickness becomes λ/4. The optical film thickness is a product of the refractive index and a physical film thickness. For example, assuming that the layer 105 is silicon oxide having the refractive index of 1.45, the layer 106 is amorphous silicon having the refractive index of 3.6, and the center wavelength is 940 nm. In this case, the light reflecting layer 112 can be designed assuming that the thickness of the layer 105 is (940 [nm]/4)/1.45≈162 [nm] and the thickness of the layer 106 is (940 [nm]/4)/3.6≈65 [nm]. In the arrangement shown in FIG. 6, the light reflecting layer 112 may be formed of, in the order from the side of the semiconductor layer 300, silicon oxide: 162 nm/amorphous silicon: 65 nm/silicon oxide: 162 nm/amorphous silicon: 65 nm/silicon oxide: 162 nm/amorphous silicon: 65 nm. As such, since the layer 106 has a refractive index higher than that of the layer 105, the thickness of the layer 105 can be designed to be larger than the thickness of the layer 106.

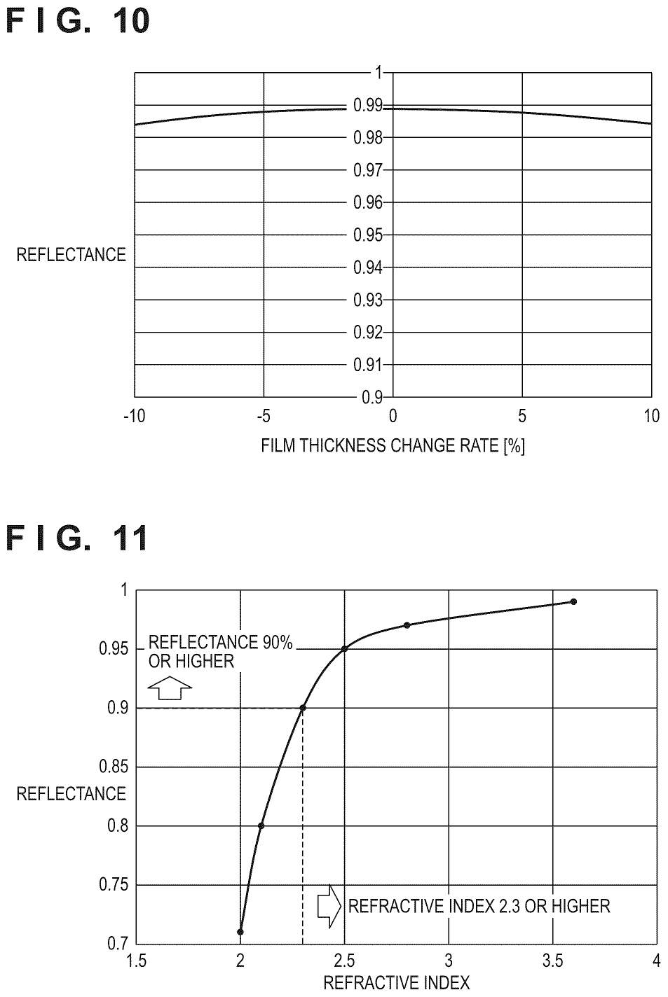

FIG. 10 shows a simulation result of the reflectance to light of the wavelength of 940 nm when the thickness of the layer 105 and the thickness of the layer 106 are simultaneously changed between ±10%. It is understood that in the film thickness variation range of ±10%, 98% or more of the reflectance is obtained for light of 940 nm. Therefore, when the thickness of the layer 105 is T1 [nm], the refractive index of the layer 105 is N1, the thickness of the layer 106 is T2 [nm], and the refractive index of the layer 106 is N2, the layer 105 and the layer 106 may be formed so as to satisfy the following:

$$N 1 \times T 1 \times 0.9 \leq λ / 4 \leq N 1 \times T 1 \times 1.1$$

$$N 2 \times T 2 \times 0.9 \leq λ / 4 \leq N 2 \times T 2 \times 1.1$$

FIG. 11 shows a simulation result of the reflectance to light at the wavelength of 940 nm when the refractive index of the layer 106 is changed. Assuming now that the layer 105 is silicon oxide (refractive index 1.45). It is understood that, in order to obtain a reflectance of 90% or higher, the layer 106 must have a refractive index of 2.3 or higher, as described above.

The light reflecting layer 112 has the configuration as described above. Accordingly, even in a case where light entered the pixel 150 of the photoelectric conversion device 100 was not fully absorbed by the semiconductor layer 300, the sensitivity can be improved by reflecting the light at the light reflecting layer 112 to the semiconductor layer 300. In this case, without need of considering the breakdown voltage between the reflective metal layer and the contact plug as shown in Japanese Patent Laid-Open No. 2022-112594, improvement of the sensitivity can be achieved with a simple structure in which the layers 105 and 106 are stacked. Further, silicon oxide, amorphous silicon, or amorphous germanium, which contain hydrogen, can be arranged as the layers 105 and 106 between the semiconductor layer 300 and the wiring layer 118 closest to the semiconductor layer 300 between the wiring layers 118 and 119 included in the wiring structure 310. Accordingly, noise characteristics of the photoelectric conversion device 100 can be improved. As a result, a photoelectric conversion device 100 of a higher performance is realized.

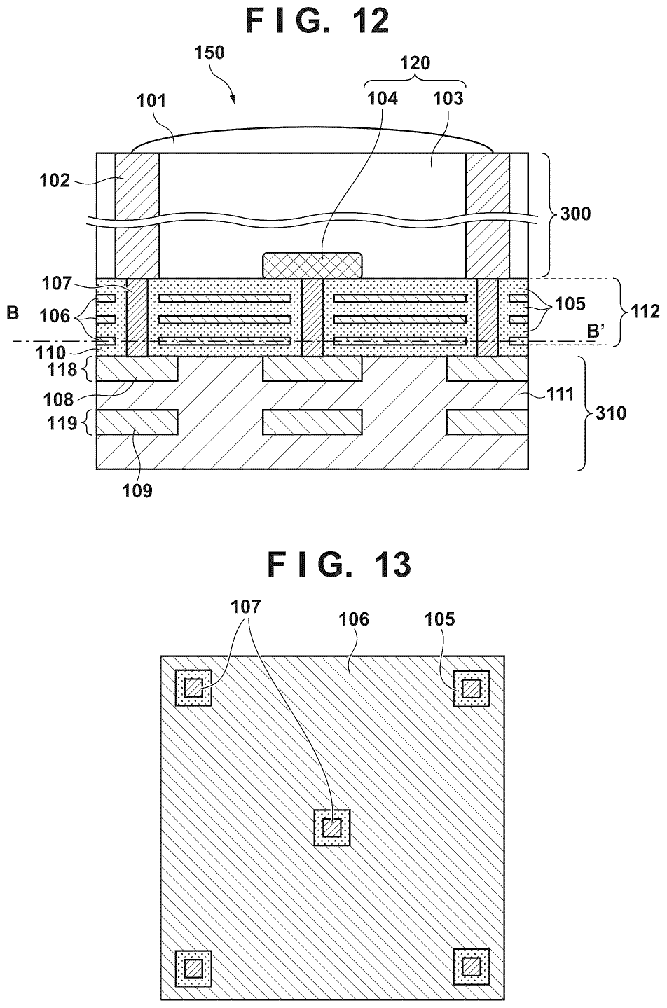

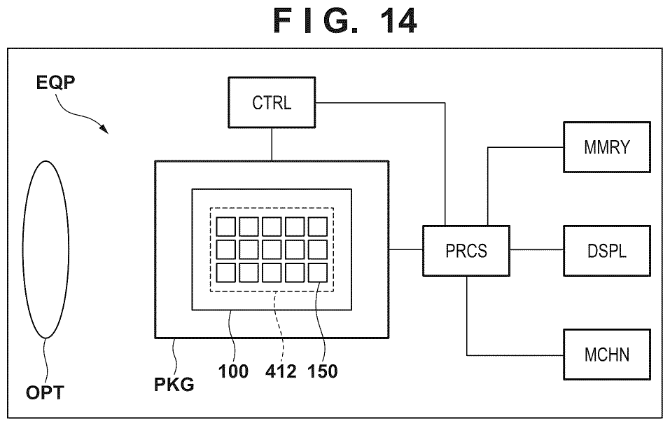

FIG. 12 is a cross-sectional view showing a modification of the pixel 150 arranged in the photoelectric conversion device 100 shown in FIG. 6. In FIG. 12, as similar to FIG. 6, the cross-section of the sensor substrate 411 is shown, and a description of the circuit substrate 421 to be arranged below the wiring structure 310 is omitted. FIG. 13 is a plan view between B-B′ of FIG. 12.

In the arrangements shown in FIGS. 6 to 9, the layer 105 and the layer 106 are each in contact with the contact plug 107. However, when forming the contact plug 107, there may be a case where it is difficult to form a through hole that penetrates the layers 105 and 106. For example, there is a case where conditions for etching the layer 105 and conditions for etching the layer 106 are greatly different and the like. Therefore, as shown in FIGS. 12 and 13, the configuration may be such that the contact plugs 107 penetrate regions where part of the layer 106 is removed. In other words, the layer 105 is in contact with the contact plugs 107, and as shown in FIG. 13, the layer 106 encloses the contact plugs 107, but between the layer 106 and the contact plug 107, the layer 105 is arranged. All other arrangements may be the same to the arrangements shown in FIGS. 6 to 9 above, and therefore an explanation thereof is omitted here.

For example, the layer 105 and the layer 106 are formed on the semiconductor layer 300, and then regions of the layer 106 where the contact plugs 107 are to be formed in a later process are etched. After etching the layer 106, a next layer 105 is formed. By repeating these processes, the light reflecting layer 112 may be formed. After forming the light reflecting layer 112 and the insulating layer 110, through holes are formed in which the contact plugs 107 are arranged. The through holes can be formed, for example, by etching the layer 105 and the insulating layer 110 that are formed of silicon oxide. Accordingly, the process of forming the through-holes in which the contact plugs 107 are arranged becomes easier, and, for example, an improvement in yield can be achieved.

An application example of the photoelectric conversion device 100 according to the embodiment described above will be explained below. FIG. 14 is a schematic view of equipment EQP incorporating the photoelectric conversion device 100. FIG. 14 shows a camera as an example of the equipment EQP. Here, the concept of the camera not only includes an apparatus whose main object is image capturing, but also an apparatus (for example, a portable terminal such as a smartphone and a personal computer) that has an image capturing function auxiliary.

The photoelectric conversion device 100 can be a semiconductor chip of a stacked structure in which the pixel regions 412 is provided. As shown in FIG. 14, the photoelectric conversion device 100 is contained in a semiconductor package PKG. The semiconductor package PKG can include a base to which the photoelectric conversion device 100 is fixed, a lid such as glass facing the photoelectric conversion device 100, and conductive connecting members, such as bonding wires or bumps that connect terminals provided in the base to terminals provided in the photoelectric conversion device 100. The equipment EQP may further include at least one of an optical system OPT, a control device CTRL, a processing device PRCS, a display device DSPL, and a storage device MMRY.

The optical system OPT is a system for forming an image on the photoelectric conversion device 100, and can be, for example, a lens, a shutter, and a mirror. The control device CTRL is a device for controlling the operation of the photoelectric conversion device 100, and can be, for example, a semiconductor device such as an ASIC or the like. The processing device PRCS is a device for processing the signal output from the photoelectric conversion device 100, and can be, for example, a semiconductor device such as a CPU, an ASIC, or the like. The display device DSPL can be an EL display device or a liquid crystal display device that displays image data obtained by the photoelectric conversion device 100. The storage device MMRY is a magnetic device or a semiconductor device that stores the image data obtained by the photoelectric conversion device 100. The storage device MMRY can be a volatile memory such as an SRAM or a DRAM, or the like, or a nonvolatile memory such as a flash memory or a hard disk drive, or the like. The mechanical device MCHN includes a moving unit or a propulsive unit such as a motor, an engine, or the like. The mechanical device MCHN in the camera can drive components of the optical system OPT for zooming, focusing, and shutter operation. In the equipment EQP, the image data output from the photoelectric conversion device 100 is displayed on the display device DSPL, or transmitted to an external device by a communication device (not shown) included in the equipment EQP. Hence, the equipment EQP may also include the storage device MMRY and the processing unit PRCS.

The camera incorporating the photoelectric conversion device 100 is also applicable to a surveillance camera or an on-board camera mounted in a transportation equipment such as an automobile, a railroad car, a ship, an airplane, or an industrial robot. In addition, the camera incorporating the photoelectric conversion device 100 is not limited to a transportation equipment but can also be applicable to equipment that widely uses object recognition, such as an Intelligent Transport System (ITS).

According to the present disclosure, it is possible to provide a technique advantageous in realizing improvement of the sensitivity with a simpler structure.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2023-116924, filed Jul. 18, 2023, which is hereby incorporated by reference herein in its entirety.

What is claimed is:

1. A photoelectric conversion device comprising: a semiconductor layer having a photoelectric conversion element; a wiring structure; and contact plug that connect the semiconductor layer and a wiring pattern arranged in a wiring layer closest to the semiconductor layer among wiring layers included in the wiring structure,
wherein a light reflecting layer through which the contact plug penetrate is arranged between the wiring layer and the semiconductor layer, and
the light reflecting layer has a periodic structure in which a first layer constituted by one of a dielectric and a semiconductor and a second layer constituted by one of a dielectric and a semiconductor that are different from the first layer are periodically stacked.

2. The device according to claim 1, wherein the first layer contains silicon oxide.

3. The device according to claim 1, wherein the second layer contains at least one of cerium oxide, niobium oxide, titanium oxide, zinc sulfide, amorphous silicon, and amorphous germanium.

4. The device according to claim 1, wherein the second layer contains one of amorphous silicon and amorphous germanium,
one of the amorphous silicon and the amorphous germanium contains 10 atom % or higher hydrogen.

5. The device according to claim 1, wherein a refractive index of the second layer is higher than a refractive index of the first layer,
a thickness of the first layer is larger than a thickness of the second layer.

6. The device according to claim 1, wherein a refractive index of the second layer is not less than 2.3.

7. The device according to claim 1, wherein when a central wavelength of light that the light reflecting layer reflects is λ [nm], a thickness of the first layer is T1 [nm], a refractive index of the first layer is N1, a thickness of the second layer is T2 [nm], and a refractive index of the second layer is N2,
$$N 1 \times T 1 \times 0.9 \leq λ / 4 \leq N 1 \times T 1 \times 1.1$$
$$N 2 \times T 2 \times 0.9 \leq λ / 4 \leq N 2 \times T 2 \times 1.1$$
is satisfied.

8. The device according to claim 1, wherein an insulating layer, through which the contact plug penetrate, is arranged between the wiring layer and the light reflecting layer, and
a refractive index of the second layer is higher than a refractive index of the insulating layer.

9. The device according to claim 8, wherein the insulating layer contains silicon oxide.

10. The device according to claim 1, wherein a refractive index of the second layer is higher than a refractive index of an interlayer insulating film constituting the wiring structure.

11. The device according to claim 10, wherein the interlayer insulating film contains at least one of silicon oxide and a material having a dielectric constant lower than silicon oxide.

12. The device according to claim 1, wherein a thickness of the light reflecting layer is not more than a height of the contact plug.

13. The device according to claim 1, wherein the photoelectric conversion element comprises an avalanche photodiode.

14. The device according to claim 1, wherein the first layer and the second layer are in contact with the contact plug.

15. The device according to claim 1, wherein the first layer is in contact with the contact plug, and
the first layer is arranged between the second layer and the contact plug.

16. Equipment comprising:
the photoelectric conversion device according to claim 1, and
a processing device configured to process a signal output from the photoelectric conversion device.
